(19) United States
(12) Patent Application Publication
(10) Pub. No.: US 2019/0137574 A1
(43) Pub. Date: May 9, 2019

(54) SYSTEM AND METHOD FOR PROLONGING BATTERY LIFE IN SOLAR-POWERED POWER STATIONS

(71) Applicant: Nova Lumos Ltd., Netanya (IL)

(72) Inventors: Nir NITZANI, Kefar Sava (IL); David VORTMAN, Tzur Moshe (IL); Nir MAROM, Tzur Moshe (IL); Rafael BONEH, Tel Aviv (IL)

(73) Assignee: Nova Lumos Ltd., Netanya (IL)

(21) Appl. No.: 16/203,126

(22) Filed: Nov. 28, 2018

Related U.S. Application Data
(63) Continuation-in-part of application No. 15/614,989, filed on Jun. 6, 2017.
(60) Provisional application No. 62/593,291, filed on Dec. 1, 2017.
(60) Provisional application No. 62/346,803, filed on Jun. 7, 2016.

(51) Int. Cl. G01R 31/392; H02S 40/38; G01R 31/387; G01R 31/382; H02J 7/35; H02J 7/00; H01M 10/44; H01M 10/42

(52) U.S. Cl. CPC G01R 31/392; H02S 40/38; G01R 31/387; G01R 31/382; H02J 7/35; H02J 7/0029; H01M 2010/4278; H01M 10/448; H01M 10/425; H02J 2007/0037; H02J 2007/004; H02J 2007/0096; H01M 2010/4271; H02J 7/007

(57) ABSTRACT

A system and method for prolonging battery life in solar-powered power stations (SPPSs). The method includes determining, based on battery usage data captured by a SPPS including a battery and a current regulator, a first maximum charge level, wherein the current regulator has configured the battery such that a current charge level of the battery does not exceed the first maximum charge level, wherein the first maximum charge level corresponds to a first expected useful life; determining a second maximum charge level for the battery based on the battery usage data, wherein the second maximum charge level corresponds to a second expected useful life that is longer than the first expected useful life; and sending, to the current regulator, reconfiguration instructions that are based on the second maximum charge level, wherein the current charge level of the reconfigured battery does not exceed the second maximum charge level.

### CROSS-REFERENCE TO RELATED APPLICATIONS

This application claims the benefit of U.S. Provisional Application No. 62/593,291 filed on Dec. 1, 2017. This application is also a continuation-in-part (CIP) of U.S. patent application Ser. No. 15/614,989 filed on Jun. 6, 2017, now pending, which claims the benefit of U.S. Provisional Application No. 62/346,803 filed on Jun. 7, 2016.

The contents of the above-referenced applications are hereby incorporated by reference.

### TECHNICAL FIELD

The present disclosure relates generally to batteries used for storing and distributing solar power, and more particularly to prolonging useful lifetimes of such batteries.

### BACKGROUND

Most rechargeable battery technologies eventually result in the battery degrading in its capacity to store charge over time. This is especially true for technologies such as lithium-ion and lithium polymer batteries. This degradation may occur due to a number of reasons, such as overcharge or deep discharge of the battery. As a result of the degradation, the battery, or in some cases an entire unit including the battery, will eventually require replacement. Frequent battery replacement is costly and inconvenient, and may be impractical in some parts of the world due to logistical concerns. Furthermore, disposal of batteries is expensive due to some environmental regulations. For some purposes, there may be an advantage to battery degradation, as this encourages users to replace devices every few years, increasing revenue for manufacturers. However, there are uses, such as off-grid power storage, where the cost of the rechargeable battery and the cost of replacement are significantly high such that it is desirable to prolong the lifetime of batteries and storage devices.

Additionally, some existing solutions focus on energy storages that typically provide power to a constant load such as, for example, a laptop battery, a phone battery, a cordless drill, and the like. As the load affects the charge-discharge cycle, the load may also affect the lifetime of the energy storage, particularly when fluctuating demands for energy are not adjusted for. Accordingly, existing solutions face challenges in adapting to dynamic loads.

It would therefore be advantageous to provide a solution that would overcome the challenges noted above.

### SUMMARY

A summary of several example embodiments of the disclosure follows. This summary is provided for the convenience of the reader to provide a basic understanding of such embodiments and does not wholly define the breadth of the disclosure. This summary is not an extensive overview of all contemplated embodiments, and is intended to neither identify key or critical elements of all embodiments nor to delineate the scope of any or all aspects. Its sole purpose is to present some concepts of one or more embodiments in a simplified form as a prelude to the more detailed description that is presented later. For convenience, the term “some embodiments” or “certain embodiments” may be used herein to refer to a single embodiment or multiple embodiments of the disclosure.

Certain embodiments disclosed herein include a method for prolonging battery life in solar-powered power stations (SPPSs). The method comprises: determining, based on battery usage data captured by a SPPS including a battery and a current regulator, a first maximum charge level, wherein the current regulator has configured the battery such that a current charge level of the battery does not exceed the first maximum charge level using energy received from at least one solar power energy source, wherein the first maximum charge level corresponds to a first expected useful life; determining a second maximum charge level for the battery based on the battery usage data, wherein the second maximum charge level corresponds to a second expected useful life, wherein the second expected useful life is longer than the first expected useful life; and sending, to the current regulator, reconfiguration instructions for reconfiguring the battery, wherein the reconfiguration instructions are based on the second maximum charge level, wherein the current charge level of the battery does not exceed the second maximum charge level when the battery is reconfigured based on the sent reconfiguration instructions.

Certain embodiments disclosed herein also include a non-transitory computer readable medium having stored thereon causing a processing circuitry to execute a process, the process comprising: determining, based on battery usage data captured by a solar-powered power station (SPPS) including a battery and a current regulator, a first maximum charge level, wherein the current regulator has configured the battery such that a current charge level of the battery does not exceed the first maximum charge level using energy received from at least one solar power energy source, wherein the first maximum charge level corresponds to a first expected useful life; determining a second maximum charge level for the battery based on the battery usage data, wherein the second maximum charge level corresponds to a second expected useful life, wherein the second expected useful life is longer than the first expected useful life; and sending, to the current regulator, reconfiguration instructions for reconfiguring the battery, wherein the reconfiguration instructions are based on the second maximum charge level, wherein the current charge level of the battery does not exceed the second maximum charge level when the battery is reconfigured based on the sent reconfiguration instructions.

Certain embodiments disclosed herein also include a system for prolonging battery life in solar-powered power stations (SPPSs). The system comprises: a processing circuitry; and a memory, the memory containing instructions that, when executed by the processing circuitry, configure the system to: determine, based on battery usage data captured by a SPPS including a battery and a current regulator, a first maximum charge level, wherein the current regulator has configured the battery such that a current charge level of the battery does not exceed the first maximum charge level using energy received from at least one solar power energy source, wherein the first maximum charge level corresponds to a first expected useful life; determine a second maximum charge level for the battery based on the battery usage data, wherein the second maximum charge level corresponds to a second expected useful life, wherein the second expected useful life is longer than the first expected useful life; and send, to the current regulator, reconfiguration instructions for reconfiguring the battery, wherein the reconfiguration instructions are based on the second maximum charge level, wherein the current charge level of the battery does not exceed the second maximum charge level when the battery is reconfigured based on the sent reconfiguration instructions.

Certain embodiments disclosed herein include a method for prolonging battery life in solar-powered power stations (SPPSs). The method comprises: determining, based on battery usage data captured by a SPPS including a battery and a current regulator, at least one first minimum charge level, wherein the current regulator has configured the battery such that a current charge level of the battery does not decrease below the first minimum charge level, wherein the first minimum charge level corresponds to a first expected useful life; determining a second minimum charge level for the battery based on the battery usage data, wherein the second minimum charge level corresponds to a second expected useful life, wherein the second expected useful life is longer than the first expected useful life; and sending, to the current regulator, reconfiguration instructions for reconfiguring the battery, wherein the reconfiguration instructions are based on the second minimum charge level, wherein the current charge level of the battery does not decrease below the second minimum charge level when the battery is reconfigured based on the sent reconfiguration instructions.

Certain embodiments disclosed herein also include a non-transitory computer readable medium having stored thereon causing a processing circuitry to execute a process, the process comprising: determining, based on battery usage data captured by a solar-powered power station (SPPS) including a battery and a current regulator, at least one first minimum charge level, wherein the current regulator has configured the battery such that a current charge level of the battery does not decrease below the first minimum charge level, wherein the first minimum charge level corresponds to a first expected useful life; determining a second minimum charge level for the battery based on the battery usage data, wherein the second minimum charge level corresponds to a second expected useful life, wherein the second expected useful life is longer than the first expected useful life; and sending, to the current regulator, reconfiguration instructions for reconfiguring the battery, wherein the reconfiguration instructions are based on the second minimum charge level, wherein the current charge level of the battery does not decrease below the second minimum charge level when the battery is reconfigured based on the sent reconfiguration instructions.

Certain embodiments disclosed herein also include a system for prolonging battery life in solar-powered power stations (SPPSs). The system comprises: a processing circuitry; and a memory, the memory containing instructions that, when executed by the processing circuitry, configure the system to: determine, based on battery usage data captured by a SPPS including a battery and a current regulator, at least one first minimum charge level, wherein the current regulator has configured the battery such that a current charge level of the battery does not decrease below the first minimum charge level, wherein the first minimum charge level corresponds to a first expected useful life; determine a second minimum charge level for the battery based on the battery usage data, wherein the second minimum charge level corresponds to a second expected useful life, wherein the second expected useful life is longer than the first expected useful life; and send, to the current regulator, reconfiguration instructions for reconfiguring the battery, wherein the reconfiguration instructions are based on the second minimum charge level, wherein the current charge level of the battery does not decrease below the second minimum charge level when the battery is reconfigured based on the sent reconfiguration instructions.

### BRIEF DESCRIPTION OF THE DRAWINGS

The subject matter disclosed herein is particularly pointed out and distinctly claimed in the claims at the conclusion of the specification. The foregoing and other objects, features, and advantages of the disclosed embodiments will be apparent from the following detailed description taken in conjunction with the accompanying drawings.

FIG. 1 is a schematic diagram of a charge control system for solar-powered power stations (SPPSs) according to an embodiment.

FIG. 2 is a schematic diagram of a solar-powered power station utilized according to an embodiment.

FIG. 3 is a network diagram illustrating a charge control system and a solar-powered-power station.

FIG. 4 is a flowchart illustrating a method for prolonging battery life of a solar-powered power station according to an embodiment.

### DETAILED DESCRIPTION

It is important to note that the embodiments disclosed herein are only examples of the many advantageous uses of the innovative teachings herein. In general, statements made in the specification of the present application do not necessarily limit any of the various claimed embodiments. Moreover, some statements may apply to some inventive features but not to others. In general, unless otherwise indicated, singular elements may be in plural and vice versa with no loss of generality. In the drawings, like numerals refer to like parts through several views.

The various disclosed embodiments include a method and system for prolonging battery life for solar-powered power stations. A solar-powered power station includes at least an energy storage (e.g., a battery unit), a communication circuit, and a charge control system. The solar-powered power station is connected to a solar power energy source such as a solar panel. The disclosed embodiments provide techniques for extending the lifespan of the energy storage.

A first set of configuration parameters is determined for an energy storage of a solar-powered power station. The first set of configuration parameters corresponds to a first battery life. A second set of configuration parameters corresponding to a second battery life is determined such that the second battery life is longer than the first battery life. The control circuit configures the energy storage based on the second set of configuration parameters, thereby extending the effective lifespan of the energy storage. The first and second sets of configuration parameters may include respective maximum charge levels, minimum charge levels, or both.

To this end, it has been identified that overcharging or excessively discharging batteries and other energy storages lowers their effective lifespans. In particular, batteries charging above or below certain threshold charge levels may have reduced lifespans. The thresholds may vary based on total capacity of the energy storage, a type of the energy storage, charging rates, discharging rates, amounts of power discharged, and the like. The disclosed embodiments include providing buffers in the form of maximum charge levels, minimum charge levels, or both, such that the effective lifespan of the energy storage is extended by avoiding overcharging or excessive discharging.

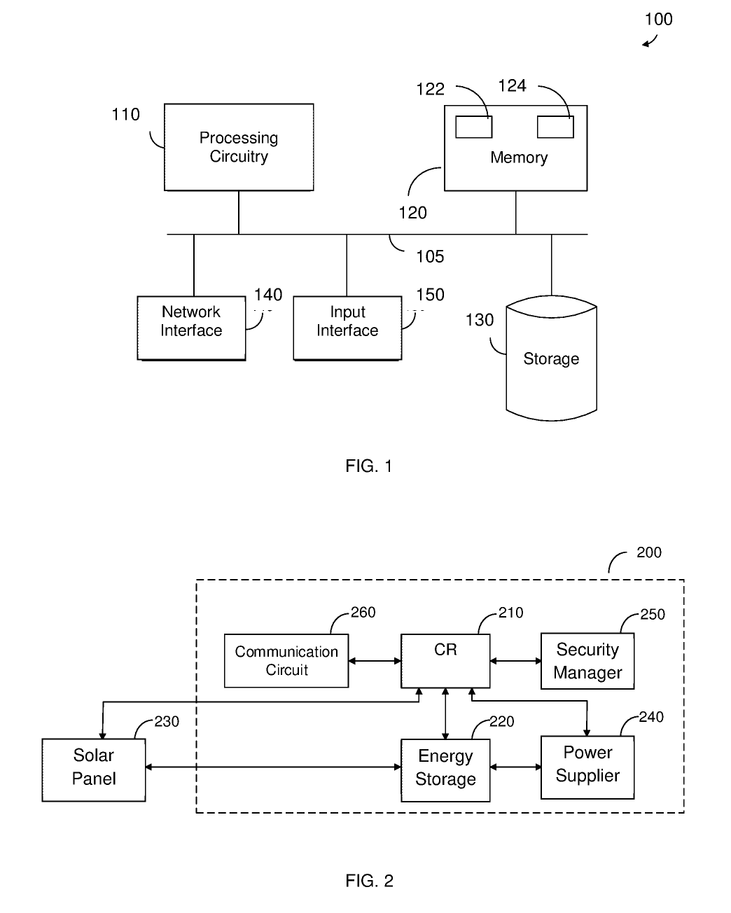

FIG. 1 shows an example schematic diagram illustrating a charge control system 100 according to an embodiment. The charge control system 100 includes a processing circuitry 110, a memory 120, a storage 130, a network interface 140, and an input/output (I/O) interface 150. In an embodiment, the components of the charge control system 100 may be communicatively connected via a bus 105.

The processing circuitry 110 may be realized as one or more hardware logic components and circuits. For example, and without limitation, illustrative types of hardware logic components that can be used include field programmable gate arrays (FPGAs), application-specific integrated circuits (ASICs), Application-specific standard products (ASSPs), system-on-a-chip systems (SOCs), general-purpose microprocessors, microcontrollers, digital signal processors (DSPs), and the like, or any other hardware logic components that can perform calculations or other manipulations of information.

The memory 120 may be volatile (e.g., RAM, etc.), non-volatile (e.g., ROM, flash memory, etc.), or a combination thereof. In one configuration, computer readable instructions to implement one or more embodiments disclosed herein may be stored in the storage 130.

Alternatively or collectively, the memory 120 may be configured to store software. Software shall be construed broadly to mean any type of instructions, whether referred to as software, firmware, middleware, microcode, hardware description language, or otherwise. Instructions may include code (e.g., in source code format, binary code format, executable code format, or any other suitable format of code). The instructions, when executed by the one or more processors, cause the processing circuitry to perform the method embodiments disclosed herein.

The memory 120 may further include a memory portion 122 containing the instructions for causing the processing circuitry 110 to perform the various disclosed embodiments. In another embodiment, the memory 120 may further include a memory portion 124 containing power measurements received from a plurality of solar-powered power stations with respect to energy sources such as solar panels of each solar-powered power station.

The storage 130 may be magnetic storage, optical storage, and the like, and may be realized, for example, as flash memory or other memory technology, CD-ROM, Digital Versatile Disks (DVDs), or any other medium which can be used to store the desired information. The storage 130 may store instructions for executing the methods as described herein.

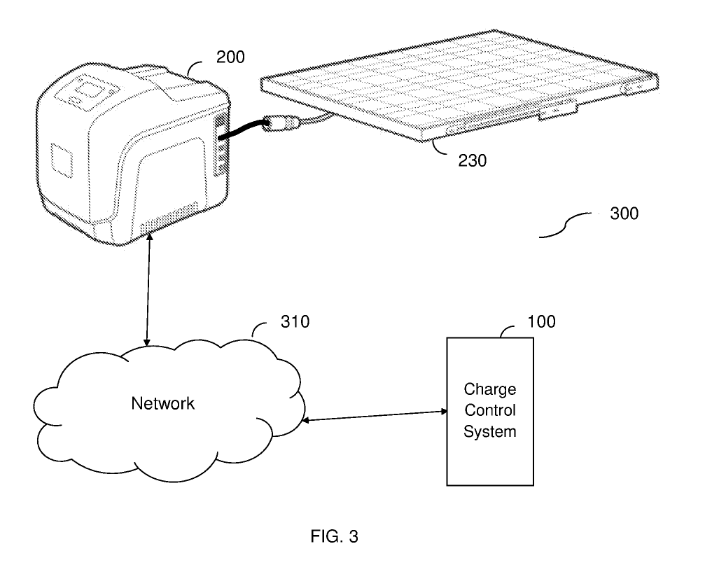

The network interface 140 and the input interface 150 allow the charge control system 100 to communicate with a network (e.g., the network 310, FIG. 3) for purposes such as, but not limited to, receiving storage data, sending instructions for reconfiguring an energy storage, and the like.

FIG. 2 is an example schematic diagram illustrating a solar-powered power station 200 utilized according to an embodiment. The solar-powered power station 200 includes a charge regulator (CR) 210 communicatively connected to an energy storage 220, a solar panel 230, a power supplier 240, a security manager 250, and a communication circuit 260. The components of the solar-powered power station 200 can be integrated into a single housing, or can be separately housed and interconnected via wires or wirelessly. In some implementations (not shown), multiple solar panels, multiple energy storages, or both, may be utilized.

In an embodiment, the charge regulator 210 is configured to control charging and discharging of energy to or from the energy storage 220. The energy storage 220 stores energy generated or otherwise provided by the solar panel 230, and the power supplier 240 obtains energy stored in the energy storage 220 for delivery to one or more energy withdrawing devices (not shown). The energy storage 220 may be or may include a rechargeable battery. In another embodiment, the energy storage may further include a capacitor or a supercapacitor.

In some implementations, the solar-powered power station 200 may be a hybrid device configure to store energy generated by the solar panel 230 and from, for example, an electrical grid (not shown). To this end, the solar-powered power station 200 may be connected to an electrical grid via, e.g., a voltage converter (not shown), and the charge regulator 210 may be configured to store energy from the electrical grid in the energy storage 220.

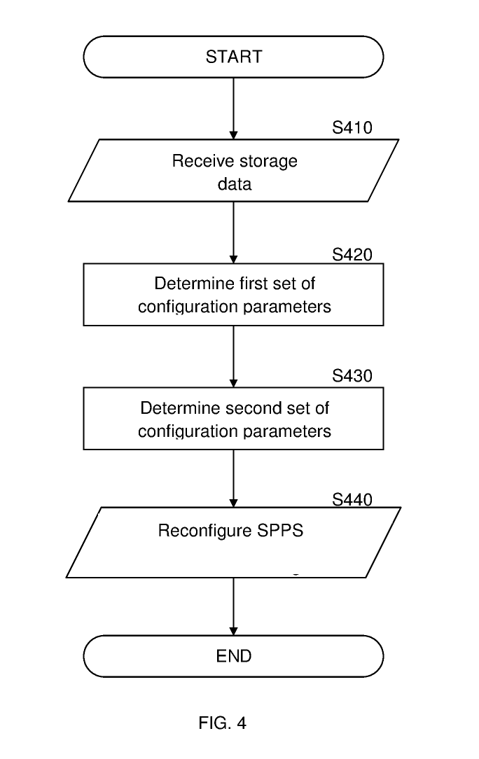

Over use during a high number of charge cycles, the energy storage 220 loses capacity. As a non-limiting example, a battery at full capacity may store a higher total amount of charge after 5 charge cycles than after 500 charge cycles. Further damage to the energy storage 220 may occur when, e.g., the energy storage 220 is overcharged or subjected to a deep discharge. To this end, in an embodiment, the charge regulator 210 is configured to control charging and discharging of the energy storage 220 based on an expected supply (i.e., an estimated load) on the energy storage 220 to prolong the useful life of the energy storage 22. Example methods for prolonging battery life are described further herein below with respect to FIG. 4.

As a non-limiting example, for a battery having a 100% capacity of 5,000 mAh (mili-Amperes per hour), an estimated load consumes current of about 2,000-3,000 mAh. Based on the estimated load, the charge regulator 210 is configured to determine a maximum charge level of 4,000 mAh (i.e., at most charged, i.e., depth of discharged, is to 80% of total capacity) and a maximum discharge level of 1,000 mAh (i.e., at most discharged down to 20% of total capacity). That is, the battery is not charged to its full capacity and not fully discharged. As a result, there may be little to no effect from a user's perspective, but the useful life of the battery (i.e., the example energy storage 220) is prolonged, thereby resulting in an increase in the total number of charge cycles the battery may perform without needing to be replaced. Specifically, there is a lower risk of deep discharge or overcharge which may result in shortening the battery's effective lifespan.

The security manager 250 may be configured to detect unauthorized access events related to the solar-powered power station 200. Unauthorized access events may include, but are not limited to, attempting to bypass the charge regulator 210, attempting to access the energy storage 220 directly, attempting to obtain energy from the solar-powered power station 200 while failing to comply with at least one access rule, and the like. The at least one access rule may include providing sufficient payment to meet a payment requirement, and may be met based on secure tokens received by the security manager 250 indicating that sufficient payment has been made.

The security manager 250 may be configured to cause the charge regulator 210 to cease distribution of power from the energy storage 220 or to enter a reduced power mode upon detection of an unauthorized access event. In an example implementation, the reduced power mode may be a “trickle” power mode such that, in the trickle power mode, the solar-powered power station 200 stores only the minimum amount of power required to maintain at least one basic function of the solar-powered power station 200 (e.g., keeping a battery sufficiently charged to prevent damage thereto). The security manager 250 may further cause the charge regulator 210 to resume a normal power mode once the unauthorized access event is over. Switching to the reduced power mode may be utilized to prevent the unauthorized access attempt while preventing damage to or failure of at least a portion of the solar-powered power station 200.

The security manager 250 may include or be communicatively connected to at least one sensor (not shown) such as, but not limited to, motion sensors, trip sensors, accelerometers, and the like, and unauthorized access events may be detected when bypass attempts are made as determined based on sensor signals from the at least one sensor. For example, an unauthorized access event may be detected when a sensor utilized to monitor a connection between the power supplier 240 and the energy storage 220 is tripped (i.e., when movement that may be related to bypassing the power supplier 240 and accessing the energy storage 220 directly is detected).

The communication circuit 260 is configured to enable communications between the solar-powered power station 200 and, for example, a network (e.g., the network 310, FIG. 3). The communications may be utilized for purposes such as, but not limited to, sending storage data, receiving instructions for reconfiguring the charge regulator 210, and the like.

The solar-powered power station 200 may include a processing circuitry (not shown) coupled to a memory (not shown). In an example implementation, the processing circuitry and memory may be included in the charge regulator 210. Some examples for implementing the processing circuity and memory in the energy storage 220 are provided above with reference to FIG. 1.

In an embodiment, the solar-powered power station 200 may further include a direct current (DC)-to-DC converter (not shown). The DC-to-DC converter may further include a regulator (not shown) configured to regulate the output voltage of the DC-to-DC converter. In such an embodiment, the charge regulator 210 may be configured to detect a faulty battery cell or group of battery cells connected in parallel. The faulty battery cells may be batter cells whose charge capacity drops faster than one or more other battery cells. When faulty battery cells are detected, the charge regulator 210 may configure a circuitry (not shown) of the energy storage 220 to bypass the faulty battery cell or group of battery cells.

It should be noted that the memory of the energy storage 220 may include instructions that, when executed by the processing circuitry, cause the processing circuitry to regulate energy charging and discharging and switching between normal and reduced power modes. The instructions may further configure the processing circuitry to determine power measurements based on energy generated by the solar panel 230, energy stored in the energy storage 220 from the solar panel 230, and the like.

FIG. 3 is an example network diagram 300 illustrating the charge control system 100 communicatively connected to the solar-powered power station 200 via a network 310. In the example network diagram 300, the solar panel 230 is a solar panel configured to charge a battery (e.g., the energy storage 220) of the solar-powered power station 200. The network 310 may be, but is not limited to, the Internet, the world-wide-web (WWW), a local area network (LAN), a wide area network (WAN), a metro area network (MAN), and other networks capable of enabling communication between the elements of the network diagram 300. In a further embodiment, the network 310 may be a cellular network.

The charge control system 100 may be configured to receive storage data from the solar-powered power station 200 via the network 310. The storage data may include, but is not limited to, energy storage capacity, energy storage charge over time, total time spent recharging the energy storage 220, rate of discharge, current supply from the energy storage 220 to another component of the solar-powered power station 200 (e.g., to the power supplier 240), and the like.

Based on the received storage data, the charge control system 100 is configured to determine at least a matching charging profile and one or more instructions for reconfiguring the charge regulator 210 to prolong the useful life of the solar-powered power station 200. The charge control system 100 may be further configured to determine an estimated useful lifetime of the energy storage 220 based on the storage data. For example, the estimated useful lifetime may be determined based on a known aging model for a type of the energy storage 220 and the storage data.

FIG. 4 is an example flowchart 400 illustrating a method for prolonging battery life according to an embodiment. In an embodiment, the method may be performed by the charge control system 100 to prolong the useful life of, e.g., the energy storage 220 of the solar-powered power station 200.

At S410, energy storage usage data is received. The energy storage usage data may be received from a solar-powered power station (e.g., the solar-powered power station 200). The energy storage usage data is related to at least one energy storage and may include data related to charging and discharging of the energy storage, circumstances related to the storage (e.g., circumstances indicating a type of the energy storage, a user of the energy storage, etc.), or both. In an embodiment, the energy storage may be a battery configured to receive energy from one or more solar panels. To this end, the first set of storage data may include, but is not limited to, energy storage capacity, energy storage charge over time, total time spent recharging the energy storage, rate of discharge, current supply from the energy storage to another component of the solar-powered power station (e.g., to a power supplier connected to the solar-powered power station), location, apparatus type, customer type, charge levels, depletion rates, and the like.

At S420, a first set of at least one configuration parameter is determined based on the first set of storage data. In an embodiment, the first set of configuration parameters includes a first maximum charge level defining a maximum amount of charge to which a current charge of the energy storage does not exceed, a first minimum charge level defining a minimum amount of charge to which a current charge of the energy storage does not decrease below, or both. In an embodiment, S420 further includes determining a first expected useful life corresponding to the first set of configuration parameters. For example, this may be performed by comparing energy storage data to a known aging model for, e.g., a battery chemistry of the energy storage. The known aging model may be utilized to determine, e.g., an estimated numbers of cycles for an energy storage such as a battery given various parameters. The first expected useful life may be determined based on the first set of configuration parameters.

In an embodiment, the first maximum charge level is lower than a total capacity of the energy storage indicated in the storage data. This may be desirable to, for example, avoid overcharging of the energy storage. Additionally, a buffer may be utilized to further reduce the likelihood of overcharging. To this end, in an example implementation, the first maximum charge level may be determined based on an initial maximum charge level and a predetermined buffer value. As a non-limiting example, when a total capacity of a battery is 5,000 mAh, a buffer value of 5% is utilized, and an initial maximum charge level is determined to be 4,000 mAh (e.g., based on the storage data), the first maximum charge level may be determined to be 3,800 mAh such that the battery is not charged to an charge level above 3,800 mAh.

At S430, a second set of at least one configuration parameter for configuring the solar-powered power station or a portion thereof is determined. In an embodiment, the second set of configuration parameters may include a second maximum charge level, a second minimum charge level, or both. In a further embodiment, S430 may include determining the second maximum charge level, the second minimum charge level, or both, based on a total load handled by the solar-powered power station during the time period. The second maximum charge level, second minimum charge level, or both, may be determined based on, e.g., a charge model and the second set of configuration parameters.

At S440, at least one instruction for reconfiguring the solar-powered power station is sent to the solar-powered power station (e.g., sent to a charge regulator of the solar-powered power station that is configured to control charging and discharging from a battery of the solar-powered power station). The at least one instruction is based on the determined second set of configuration parameters such that the battery charges with respect to limits (e.g., a maximum charge level, a minimum charge level, or both) among the second set of configuration parameters. In an embodiment, S440 may further include determining a second estimated useful life with respect to the second set of configuration parameters. The second estimated useful life is longer than the first estimated useful life. The second estimated useful life may be determined based on the aging model for the energy storage and the second set of configuration parameters.

It should be noted that various embodiments disclosed herein are described with respect to prolonging battery life merely for simplicity purposes and without limitation on the disclosed embodiments. Useful lifetimes of energy storages other than batteries that may be charged and discharged and may degrade in performance over time due to, e.g., overcharging or deep discharging, may be equally prolonged without departing from the scope of the disclosure.

The various embodiments disclosed herein can be implemented as hardware, firmware, software, or any combination thereof. Moreover, the software is preferably implemented as an application program tangibly embodied on a program storage unit or computer readable medium consisting of parts, or of certain devices and/or a combination of devices. The application program may be uploaded to, and executed by, a machine comprising any suitable architecture. Preferably, the machine is implemented on a computer platform having hardware such as one or more central processing units (“CPUs”), a memory, and input/output interfaces. The computer platform may also include an operating system and microinstruction code. The various processes and functions described herein may be either part of the microinstruction code or part of the application program, or any combination thereof, which may be executed by a CPU, whether or not such a computer or processor is explicitly shown. In addition, various other peripheral units may be connected to the computer platform such as an additional data storage unit and a printing unit. Furthermore, a non-transitory computer readable medium is any computer readable medium except for a transitory propagating signal.

All examples and conditional language recited herein are intended for pedagogical purposes to aid the reader in understanding the principles of the disclosed embodiment and the concepts contributed by the inventor to furthering the art, and are to be construed as being without limitation to such specifically recited examples and conditions. Moreover, all statements herein reciting principles, aspects, and embodiments of the disclosed embodiments, as well as specific examples thereof, are intended to encompass both structural and functional equivalents thereof. Additionally, it is intended that such equivalents include both currently known equivalents as well as equivalents developed in the future, i.e., any elements developed that perform the same function, regardless of structure.

It should be understood that any reference to an element herein using a designation such as “first,” “second,” and so forth does not generally limit the quantity or order of those elements. Rather, these designations are generally used herein as a convenient method of distinguishing between two or more elements or instances of an element. Thus, a reference to first and second elements does not mean that only two elements may be employed there or that the first element must precede the second element in some manner. Also, unless stated otherwise, a set of elements comprises one or more elements.

As used herein, the phrase “at least one of” followed by a listing of items means that any of the listed items can be utilized individually, or any combination of two or more of the listed items can be utilized. For example, if a system is described as including “at least one of A, B, and C,” the system can include A alone; B alone; C alone; 2A; 2B; 2C; 3A; A and B in combination; B and C in combination; A and C in combination; A, B, and C in combination; 2A and C in combination; A, 3B, and 2C in combination; and the like.

What is claimed is:

1. A method for prolonging battery life in solar-powered power stations (SPPSs), comprising:
determining, based on battery usage data captured by a SPPS including a battery and a current regulator, a first maximum charge level, wherein the current regulator has configured the battery such that a current charge level of the battery does not exceed the first maximum charge level using energy received from at least one solar power energy source, wherein the first maximum charge level corresponds to a first expected useful life;
determining a second maximum charge level for the battery based on the battery usage data, wherein the second maximum charge level corresponds to a second expected useful life, wherein the second expected useful life is longer than the first expected useful life; and
sending, to the current regulator, reconfiguration instructions for reconfiguring the battery, wherein the reconfiguration instructions are based on the second maximum charge level, wherein the current charge level of the battery does not exceed the second maximum charge level when the battery is reconfigured based on the sent reconfiguration instructions.

2. The method of claim 1, further comprising:
determining a first minimum charge level based on the battery usage data, wherein the current regulator has configured the battery such that the current charge level of the battery does not decrease below the first minimum charge level, wherein the first minimum charge level corresponds to the first expected useful life.

3. The method of claim 2, further comprising:
determining a second minimum charge level for the battery based on the battery usage data, wherein the second minimum charge level corresponds to the second expected useful life, wherein the reconfiguration instructions are further based on the second minimum charge level, wherein the current charge level of the battery does not decrease below the second minimum charge level when reconfigured based on the sent reconfiguration instructions.

4. The method of claim 1, wherein the at least one solar power energy source includes at least one solar panel.

5. The method of claim 1, wherein the battery usage data includes a battery capacity of the battery.

6. A non-transitory computer readable medium having stored thereon instructions for causing a processing circuitry to execute a process, the process comprising:
determining, based on battery usage data captured by a solar-powered power station (SPPS) including a battery and a current regulator, a first maximum charge level, wherein the current regulator has configured the battery to charge at most to the first maximum charge level using energy received from at least one solar power energy source, wherein the first maximum charge level corresponds to a first expected useful life;
determining a second maximum charge level for the battery based on the battery usage data, wherein the second maximum charge level corresponds to a second expected useful life, wherein the second expected useful life is longer than the first expected useful life; and
sending, to the current regulator, reconfiguration instructions for reconfiguring the battery, wherein the reconfiguration instructions are based on the second maximum charge level, wherein the battery charges at most to the second maximum charge level when reconfigured based on the sent reconfiguration instructions.

7. A system for prolonging battery life in solar-powered power stations (SPPSs), comprising:
a processing circuitry; and
a memory, the memory containing instructions that, when executed by the processing circuitry, configure the system to:
determine, based on battery usage data captured by a SPPS including a battery and a current regulator, a first maximum charge level, wherein the current regulator has configured the battery to charge at most to the first maximum charge level using energy received from at least one solar power energy source, wherein the first maximum charge level corresponds to a first expected useful life;
determine a second maximum charge level for the battery based on the battery usage data, wherein the second maximum charge level corresponds to a second expected useful life, wherein the second expected useful life is longer than the first expected useful life; and
send, to the current regulator, reconfiguration instructions for reconfiguring the battery, wherein the reconfiguration instructions are based on the second maximum charge level, wherein the battery charges at most to the second maximum charge level when reconfigured based on the sent reconfiguration instructions.

8. The system of claim 7, wherein the system is further configured to:
determine a first minimum charge level based on the battery usage data, wherein the current regulator has configured the battery such that the current charge level of the battery does not decrease below the first minimum charge level, wherein the first minimum charge level corresponds to the first expected useful life.

9. The system of claim 8, wherein the system is further configured to:
determine a second minimum charge level for the battery, wherein the second minimum charge level corresponds to the second expected useful life, wherein the reconfiguration instructions are further based on the second minimum charge level, wherein the current charge level of the battery does not decrease below the second minimum charge level when reconfigured based on the sent reconfiguration instructions.

10. The system of claim 7, wherein the at least one solar power energy source includes at least one solar panel

11. The system of claim 7, wherein the battery usage data includes a battery capacity of the battery.

12. A method for prolonging battery life in solar-powered power stations (SPPSs), comprising:
determining, based on battery usage data captured by a SPPS including a battery and a current regulator, at least one first minimum charge level, wherein the current regulator has configured the battery such that a current charge level of the battery does not decrease below the first minimum charge level, wherein the first minimum charge level corresponds to a first expected useful life;
determining a second minimum charge level for the battery based on the battery usage data, wherein the second minimum charge level corresponds to a second expected useful life, wherein the second expected useful life is longer than the first expected useful life; and
sending, to the current regulator, reconfiguration instructions for reconfiguring the battery, wherein the reconfiguration instructions are based on the second minimum charge level, wherein the current charge level of the battery does not decrease below the second minimum charge level when the battery is reconfigured based on the sent reconfiguration instructions.

13. The method of claim 12, wherein the at least one solar power energy source includes at least one solar panel.

14. The method of claim 12, wherein the battery usage data includes a battery capacity of the battery.

15. A non-transitory computer readable medium having stored thereon instructions for causing a processing circuitry to execute a process, the process comprising:
determining, based on battery usage data captured by a SPPS including a battery and a current regulator, at least one first minimum charge level, wherein the current regulator has configured the battery such that a current charge level of the battery does not decrease below the first minimum charge level, wherein the first minimum charge level corresponds to a first expected useful life;
determining a second minimum charge level for the battery based on the battery usage data, wherein the second minimum charge level corresponds to a second expected useful life, wherein the second expected useful life is longer than the first expected useful life; and
sending, to the current regulator, reconfiguration instructions for reconfiguring the battery, wherein the reconfiguration instructions are based on the second minimum charge level, wherein the current charge level of the battery does not decrease below the second minimum charge level when the battery is reconfigured based on the sent reconfiguration instructions.

16. A system for prolonging battery life in solar-powered power stations (SPPSs), comprising:
a processing circuitry; and
a memory, the memory containing instructions that, when executed by the processing circuitry, configure the system to:
determine, based on battery usage data captured by a SPPS including a battery and a current regulator, at least one first minimum charge level, wherein the current regulator has configured the battery such that a current charge level of the battery does not decrease below the first minimum charge level, wherein the first minimum charge level corresponds to a first expected useful life;
determine a second minimum charge level for the battery based on the battery usage data, wherein the second minimum charge level corresponds to a second expected useful life, wherein the second expected useful life is longer than the first expected useful life; and
send, to the current regulator, reconfiguration instructions for reconfiguring the battery, wherein the reconfiguration instructions are based on the second minimum charge level, wherein the current charge level of the battery does not decrease below the second minimum charge level when the battery is reconfigured based on the sent reconfiguration instructions.

17. The system of claim 16, wherein the at least one solar power energy source includes at least one solar panel.

18. The system of claim 16, wherein the battery usage data includes a battery capacity of the battery.
